(19) United States
(12) Patent Application Publication
(10) Pub. No.: US 2012/0202347 A1
(43) Pub. Date: Aug. 9, 2012

(54) THROUGH SILICON VIAS USING CARBON NANOTUBES

(75) Inventors: WILLIAM JUDSON READY, Atlanta, GA (US); Stephan Turano, Atlanta, GA (US)

(73) Assignee: Georgia Tech Research Corporation, Atlanta, GA (US)

(21) Appl. No.: 13/366,545

(22) Filed: Feb. 6, 2012

Related U.S. Application Data
(60) Provisional application No. 61/440,074, filed on Feb. 7, 2011.

(51) Int. Cl. H01L 21/768

(52) U.S. Cl. 438/666; 257/E21.586

(57) ABSTRACT

The various embodiments of the present invention provide carbon nanotube (CNT)-based TSVs and methods of making the same. The CNT-based TSVs embodiments comprise a silicon wafer having a plurality of through-vias defined therein, and a support layer comprising a CNT catalyst layer disposed beneath the silicon wafer to facilitate CNT growth through the plurality of through-vias. Once CNT arrays have grown inside and through the through-vias, the support layer and accompanying CNT catalyst layer can be removed from the silicon wafer, which will result in the CNTs remaining in the TSVs.

### CROSS-REFERENCE TO RELATED APPLICATIONS

This application claims the benefit of U.S. Provisional Patent Application Ser. No. 61/440,074, filed 7 Feb. 2011, which is incorporated herein by reference in its entirety as if fully set forth below.

### BACKGROUND

1. Field

The various embodiments of the present invention relate to through silicon vias and methods of making and using the same.

2. Description of Related Art

Through silicon vias (TSVs) have garnered increasing interest in the microelectronics and packaging industry because of their shorter vertical interconnect path, which results in lower parasitic losses, reduced power consumption, higher I/O density, and improved system performance. Current studies focus on the fabrication, characterization, modeling, assembly, and reliability testing of copper and other metal-based TSVs. Although copper-based TSVs continue to show significant promise, they suffer from several fabrication and reliability challenges, for example, (1) defect-free fabrication of high aspect ratio copper-filled TSVs is challenging, (2) voids are increasingly common in copper TSVs, which leads to electromigration and joule-heating based failures, (3) the coefficient of thermal expansion (CTE) mismatch between copper and the surrounding silicon oxide (SiO₂) and silicon (Si) leads to high thermo-mechanical stresses which potentially leads to cracking or delamination of silicon oxide, (4) the high CTE of copper results in copper pumping at high temperatures, which leads to the failure of dielectric layers deposited on the top, and (5) the higher resistivity of copper at smaller dimensions leads to electrical and thermal bottleneck as TSV dimensions are scaled down.

In view of the above-mentioned electromechanical and thermomechanical challenges with copper TSVs, there is a compelling need to explore alternate materials for TSVs. It is to this need that the present invention is directed.

### BRIEF SUMMARY

Exemplary embodiments of the present invention provide CNT-based TSVs and methods of making the same. In one embodiment, the method of making through silicon vias with carbon nanotube interconnects comprises placing a silicon wafer mold comprising a plurality of holes onto a carbon nanotube growth source; forming carbon nanotubes within at least a portion of the plurality of holes; and separating the carbon nanotube growth source from the silicon wafer mold so that the carbon nanotubes formed within at least a portion of the plurality of holes remain substantially within the plurality of holes, thereby forming through silicon vias.

The method can further comprise patterning a top surface of the silicon wafer.

In some embodiments, the carbon nanotube growth source comprises metal, for example, iron, nickel, or cobalt.

The method can even further comprise forming electrical contacts on at least a portion of the carbon nanotubes.

In some embodiments, the carbon nanotube growth source can be separated from the silicon wafer mold via shearing.

Further, the plurality of holes in the silicon wafer can have an average diameter of between about 10 and about 100 micrometers and an average depth of between about 150 and about 500 micrometers.

In other exemplary embodiments, the method of making through silicon vias utilizing carbon nanotubes comprises coating a bottom surface of a silicon wafer with a carbon nanotube catalyst layer followed by support layer; etching a plurality of holes through the silicon wafer such that the plurality of holes extend from a top surface of the silicon wafer to the bottom side of the silicon wafer but do not penetrate the carbon nanotube catalyst layer or support layer; and growing carbon nanotubes through at least a portion of the plurality of holes.

The method can further comprise patterning the top surface of the silicon wafer.

In some embodiments, the carbon nanotube catalyst layer is a metal, for example, iron, nickel, or cobalt.

In other embodiments, the carbon nanotube catalyst layer can be about 0.5 to about 10 nanometers in thickness. Further, the support layer can be about 5 micrometers or less in thickness. Even further, the silicon wafer can be about 150 to about 500 micrometers in thickness.

The silicon wafer mold can be further selectively metalized with an additional metal to serve as an electrical contact layer. In some embodiments, the method can further comprise forming metal electrical contacts on at least a portion of the carbon nanotubes.

In yet other embodiments, the carbon nanotube catalyst layer can also be an electrical contact layer.

In some embodiments, the method can further comprise separating the silicon wafer mold from the carbon nanotube catalyst layer and oxide layer via shearing, chemical or plasma etching, or polishing.

Further, the support layer is an oxide layer and can be made of a material having a higher melting temperature than the carbon nanotube deposition temperature. Further, the carbon nanotubes are grown using a chemical vapor deposition process.

### FIGURES

FIG. 1 illustrates an embodiment of a silicon wafer, a carbon nanotube source layer, and an oxide layer, in accordance with exemplary embodiments of the present invention.

FIG. 2 illustrates an embodiment of a “holey” silicon wafer, a carbon nanotube source layer, and an oxide layer, in accordance with exemplary embodiments of the present invention.

FIG. 3 provides a scanning electron microscope (SEM) image of a four-cycle etching process, in accordance with exemplary embodiments of the present invention.

FIGS. 4-6 provide SEM images of etched holes through the silicon wafer of different diameters and depths, in accordance with exemplary embodiments of the present invention.

FIG. 7 graphically illustrates a chemical vapor deposition (CVD) growth temperature profile for an exemplary growth method.

FIG. 8 provides an SEM image of a TSV partially filled with a carbon nanotube (CNT) array, in accordance with exemplary embodiments of the present invention.

FIG. 9 provides an SEM image of two TSVs partially filled with a CNT array, in accordance with exemplary embodiments of the present invention.

FIG. 10 provides an SEM image of a TSV partially filled with a CNT array, in accordance with exemplary embodiments of the present invention.

### DETAILED DESCRIPTION

Referring now to the figures, wherein like reference numerals represent like parts throughout the several views, exemplary embodiments of the present invention will be described in detail. Throughout this description, various components can be identified as having specific values or parameters, however, these items are provided as exemplary embodiments. Indeed, the exemplary embodiments do not limit the various aspects and concepts of the present invention as many comparable parameters, sizes, ranges, and/or values can be implemented.

It should also be noted that, as used in the specification and the appended claims, the singular forms “a,” “an,” and “the” include plural references unless the context clearly dictates otherwise. For example, reference to a component is intended also to include composition of a plurality of components. References to a composition containing “a” constituent is intended to include other constituents in addition to the one named. Also, in describing the preferred embodiments, terminology will be resorted to for the sake of clarity. It is intended that each term contemplates its broadest meaning as understood by those skilled in the art and includes all technical equivalents which operate in a similar manner to accomplish a similar purpose.

Values may be expressed herein as “about” or “approximately” one particular value, this is meant to encompass the one particular value and other values that are relatively close but not exactly equal to the one particular value. By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a composition does not preclude the presence of additional components than those expressly identified.

The various embodiments of the present invention provide carbon nanotube (CNT)-based TSVs and methods of making the same. CNT-based TSVs pose many advantages over copper-based TSVs. Generally, CNT-based TSVs handle heat transfer and heat dissipation more efficiently than copper and thus can provide more power in smaller packages. Further, very fine pitch and high aspect ratio TSVs that are not possible with copper can be realized through CNT-based TSVs. More specifically, (1) the CTE mismatch between CNT and the surrounding silicon oxide (SiO₂) and silicon (Si) is low, and therefore thermo-mechanical stresses will be lower, (2) fabricated CNTs at densities varying from about 5-10% have a modulus ranging from about 0.5 to 2.0 MPa and thus stresses induced by the CNTs on surrounding materials (including dielectric materials) will be low, (3) CNTs are good electrical and thermal conductors, and thus they do not suffer from overheating or electrical parasitics, (4) electromigration is not a concern with CNTs, (5) voids are naturally present in CNT bundles and do not present major adverse effects, and (6) CNTs can be fabricated in existing cleanroom infrastructure and thus can be easily integrated.

Exemplary embodiments of the present invention comprise a silicon wafer having a plurality of through-vias defined therein, and a support layer comprising a CNT catalyst layer disposed beneath the silicon wafer to facilitate CNT growth through the plurality of through-vias. Once CNT arrays have grown inside and through the through-vias, the support layer and accompanying CNT catalyst layer can be removed from the silicon wafer, which will result in the CNTs remaining in the TSVs.

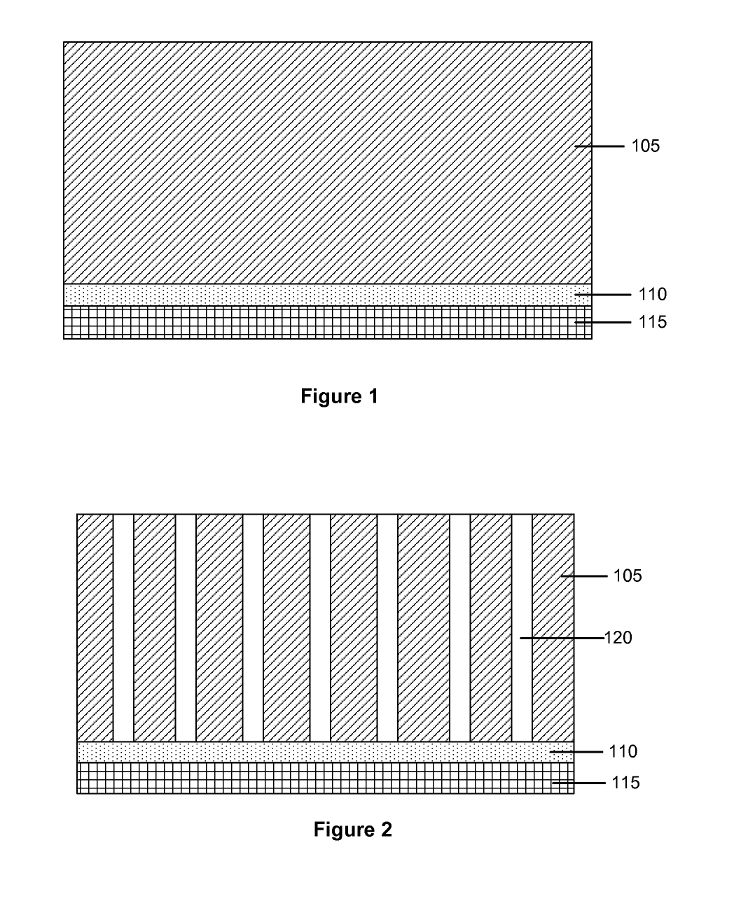

Referring to FIG. 1, there is shown a silicon wafer 105. In exemplary embodiments, the silicon wafer 105 can be about 150 to about 500 micrometers (μm) in thickness. More preferably, the silicon wafer 105 is about 300 to about 325 micrometers in thickness. On the bottom surface of the silicon wafer 105, there is disposed a CNT growth source 110. The carbon nanotube source 110 is a CNT catalyst/support system for subsequent CNT growth and is disposed on a support layer 115. In exemplary embodiments, the CNT growth source 110 and support layer 115 are disposed on the bottom side of the silicon wafer 105 via chemical vapor deposition (CVD) techniques.

Further, in exemplary embodiments, the CNT growth source 110 can be iron, nickel, cobalt, other similar metals, or mixtures thereof. The support layer 115 can be an oxide layer, for example silicon oxide or aluminum oxide, or of a material having a higher melting temperature than the carbon nanotube deposition temperature to keep the CNT growth source 110 from diffusing through the support layer 115 during manufacturing. In exemplary embodiments, the CNT growth source 110 can be about 0.5 to about 10 nanometers in thickness, and more preferably, approximately three nanometers in thickness. Further, the support layer 115 can be about one to about five micrometers in thickness, and more preferably, about two micrometers in thickness.

The top side of the silicon wafer 105 can be desirably patterned via photolithography methods or other patterning methods. A plurality of holes can then be etched through the silicon wafer to form a plurality of TSVs, as illustrated in FIG. 2. The plurality of holes 120 are etched from the top surface of the silicon wafer 105 to the bottom surface of the silicon wafer 105. The plurality of holes 120 do not extend through to the CNT growth source 110 and support layer 115, however. In exemplary embodiments, an STS “Pegasus” DRIE etch tool is used to etch the plurality of holes 120, however other etching techniques can be used as well. The plurality of TSVs 120 in the silicon wafer 105 can have an average diameter of between about 10 and about 100 micrometers and an average depth of between about 150 and about 500 micrometers (thus corresponding to the overall thickness of the silicon wafer 105).

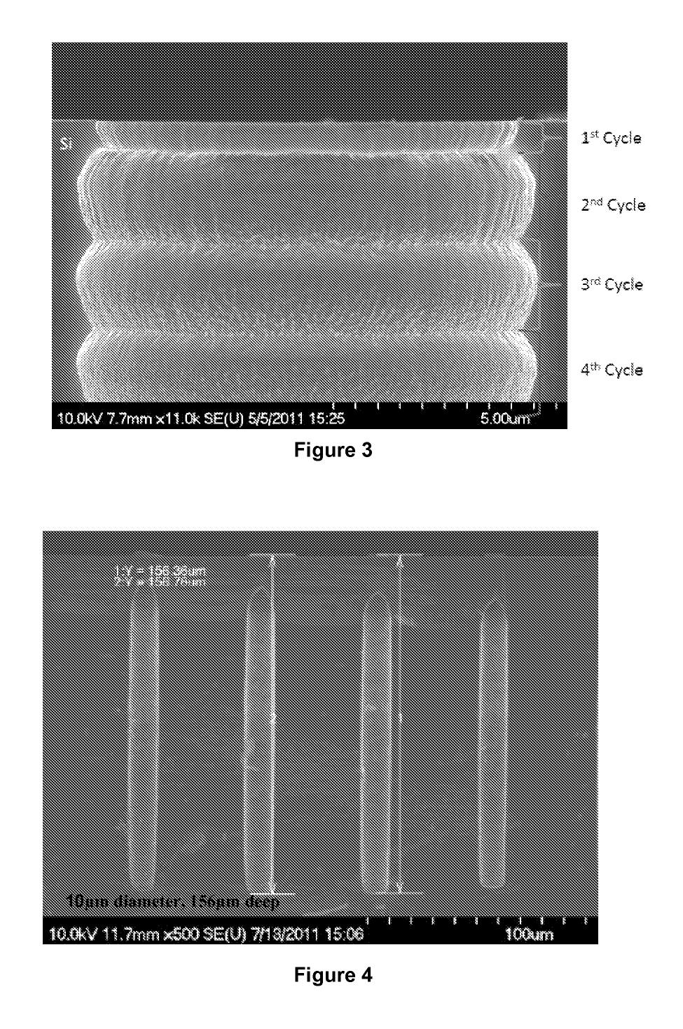

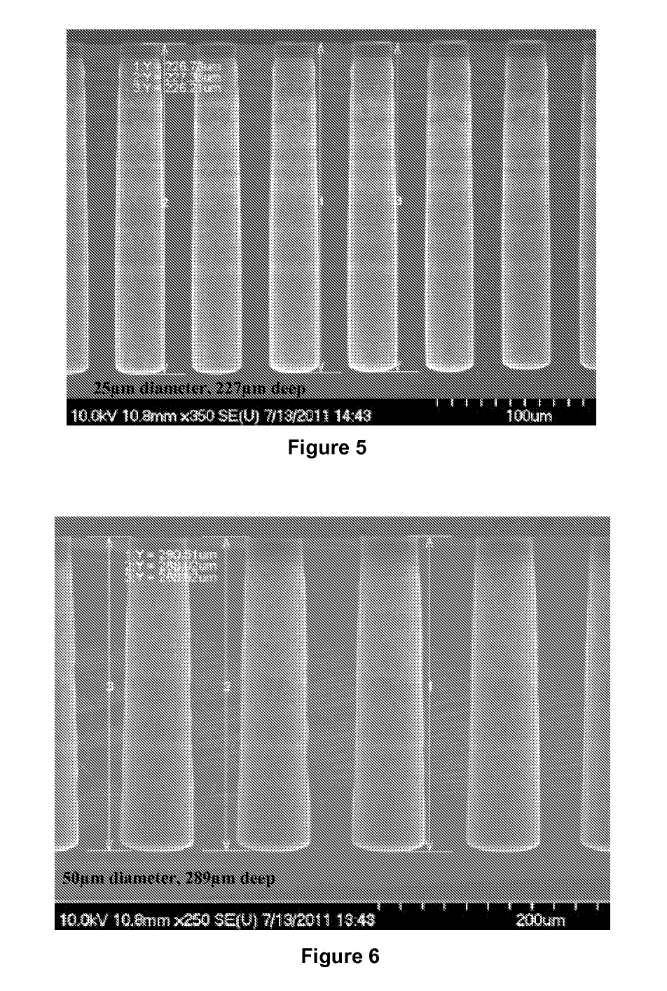

The etching process is a two-step process, including (1) a deposition phase and (2) an etching phase. One cycle includes both steps and removes at least a portion of the silicon material from the silicon wafer 105 and initiates the formation of the TSVs 120. The number of cycles is dependent on the thickness of the silicon wafer 105. For example, the thicker the silicon wafer, the more cycles are needed as each cycle removes only a portion of the silicon wafer. In exemplary methods, the number of cycles necessary to achieve fully extended TSVs 120 ranges from about 130 cycles to about 200 cycles. Referring to FIG. 3, there is shown a scanning electron microscope (SEM) image of a four-cycle etching process. Referring to FIGS. 4-6, there is shown SEM images of etched holes through the silicon wafer of different diameters and depths.

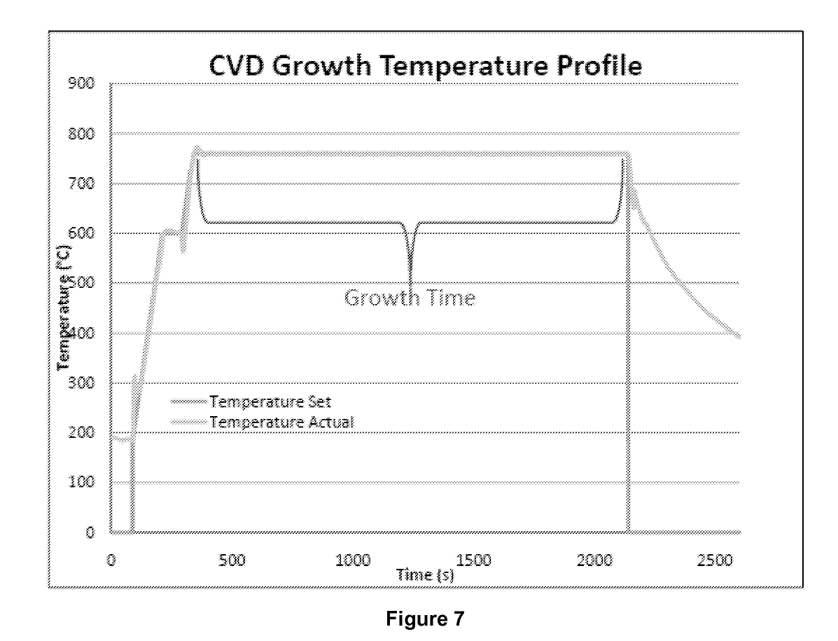

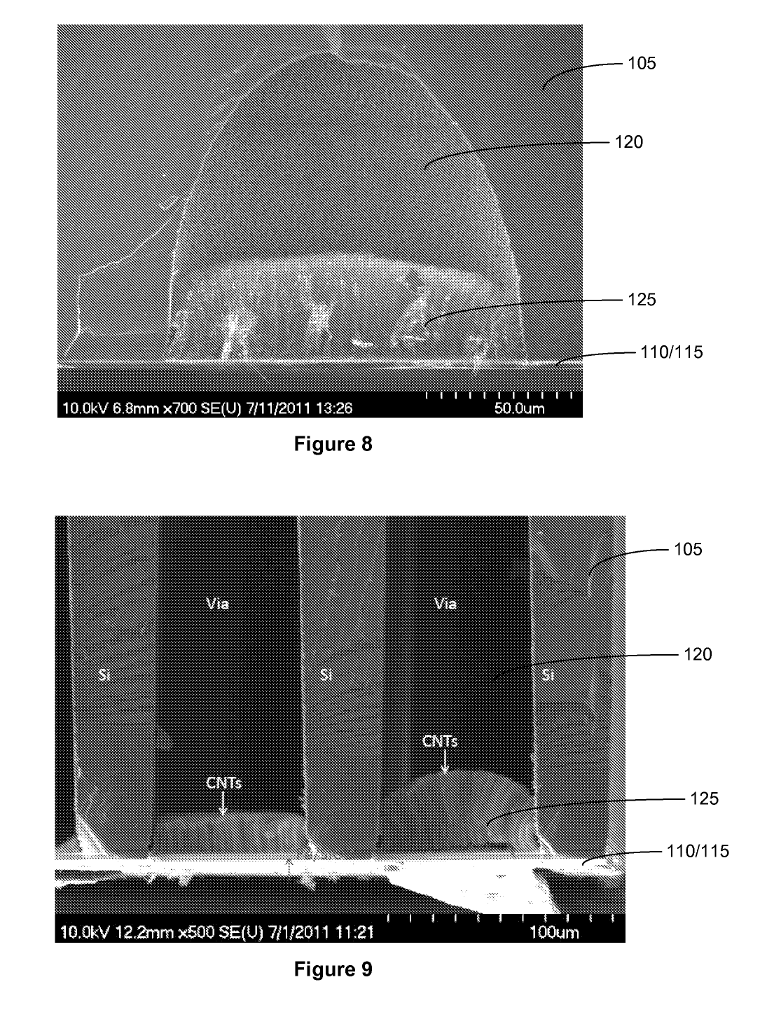

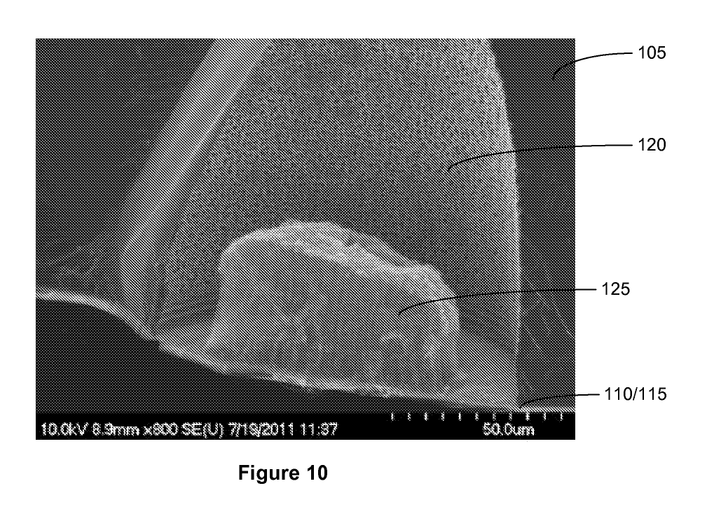

After the TSVs 120 are formed through the silicon wafer 105 via etching techniques, chemical vapor deposition (CVD) techniques can then be applied to the silicon wafer 105, the CNT growth source 110, and the oxide layer 115, which facilitates CNT formation and growth through the TSVs 120. CNT arrays will grow from the CNT growth source 110 and underlying oxide layer 115 and fill each of the TSVs at least partially, if not substantially or completely. Referring to FIG. 7, there is graphically shown a CVD growth temperature profile for an exemplary growth method. As illustrated, and in exemplary embodiments, the growth of the CNT arrays within the TSVs 120 occurs around a temperature of about 750° C. and takes about 20 to 30 minutes to fill. Referring to FIGS. 8-10, there is shown SEM images of CNT arrays inside the plurality of holes. In FIG. 8, there is shown an image of CNT arrays partially filling a TSV. In FIG. 9, there is shown two TSVs 120 etched within a silicon wafer 105, each TSV 120 comprising CNT arrays that partially fill the TSVs 120. In FIG. 10, there is shown a three-dimensional image of CNT arrays partially filling a TSV.

Once the CNT-based TSVs are completed, the remaining CNT growth source layer 110 and oxide layer 115 can be removed from the silicon wafer via shearing, chemical or plasma etching, or polishing techniques without having to planarize or buff the layers. Alternatively, in an embodiment of the present invention, the carbon nanotube source can include a catalyst metal that can also act as a conductive material. An electrical contact layer can be added to the carbon nanotube source, thereby creating an electrical contact without the additional step of shearing off the CNT growth source. Prior art TSVs were traditionally created by removing a portion of the growth surface using physical techniques, such as for example planarizing or buffing the lower silicon surface, to expose at least the lower portion of the TSV material. The prior art techniques were hampered by including additional process steps, by introducing foreign and by removing portions of the TSV material. The present invention overcomes these traditional shortcomings.

The resultant product is CNT-based TSVs that have improved characteristics over cooper TSVs of the prior art.

### Example

Described herein is an exemplary method of making the embodiment of the present invention. It shall be understood that other methods of making can be used and the present invention shall not be limited solely to the method described herein.

First, a thin film of a CNT catalytic material is deposited onto a polished backside of a silicon wafer via electron beam evaporation, sputtering, or other similar methods. A film of catalyst support material, typically an oxide material is deposited on top of the catalyst film. The polished topside of the silicon wafer is then patterned via photolithography, electron beam lithography, nano-imprint lithography or similar patterning methods.

The top side of the wafer is then etched via a switched Bosch-type etch process. In this etch, the patterning media (i.e., photoresist or similar material) serves to mask areas which will not be etched. The silicon which is not covered by patterned media is exposed to alternating cycles of etching and protective gases in a plasma environment. An etch cycle typically uses 450 standard cubic centimeters per minute (sccm) SF₆ gas under a coil power of 2800 watts (W) with 40 W platen power. The chamber pressure is typically 100 mTorr at a temperature of 20° C. The silicon is exposed to this gas for around 7 s.

The deposition cycle of the process typically uses 250 sccm C₄F₈ gas under a coil power of 2600 W. The chamber pressure is typically 30 mTorr at a temperature of 20° C. The silicon is exposed to this gas for around 3 to 3.5 seconds. A succession of these cycles (many tens or hundreds of cycles) are used to etch through the silicon wafer, and the etch is stopped at the catalyst layer at the base of the wafer.

CNTs are subsequently grown via a chemical vapor deposition or similar process. This process generally takes places under temperatures ranging from 650-850° C. in the presence of a reducing agent (H₂, NH₃ or similar gas) and a carbon source (C₂H₂, CH₄, or similar gas). Additionally, an inert gas such as Ar or N is also present in the process chamber. The CNT growth can take place under a wide range of pressures, from a few mTorr to atmospheric pressure or higher. The CNT growth process may take up to 60 minutes depending on the desired length of the CNTs being grown.

Numerous characteristics and advantages have been set forth in the foregoing description, together with details of structure and function. While the invention has been disclosed in several forms, it will be apparent to those skilled in the art that many modifications, additions, and deletions, especially in matters of shape, size, and arrangement of parts, can be made therein without departing from the spirit and scope of the invention and its equivalents as set forth in the following claims. Therefore, other modifications or embodiments as may be suggested by the teachings herein are particularly reserved as they fall within the breadth and scope of the claims here appended.

We claim:

1. A method of making through silicon vias with carbon nanotube interconnects, the method comprising:
placing a silicon wafer mold comprising a plurality of holes onto a carbon nanotube growth source;
forming carbon nanotubes within at least a portion of the plurality of holes; and
separating the carbon nanotube growth source from the silicon wafer mold so that the carbon nanotubes formed within at least a portion of the plurality of holes remain substantially within the plurality of holes, thereby forming through silicon vias.

2. The method of claim 1, further comprising patterning a top surface of the silicon wafer.

3. The method of claim 1, wherein the carbon nanotube growth source comprises a metal.

4. The method of claim 3, wherein the metal is iron, nickel, or cobalt.

5. The method of claim 1, further comprising forming metal electrical contacts on at least a portion of the carbon nanotubes.

6. The method of claim 1, wherein the carbon nanotube growth source is separated from the silicon wafer mold via shearing.

7. The method of claim 1, wherein the plurality of holes in the silicon wafer have an average diameter of between about 10 and about 100 micrometers and an average depth of between about 150 and about 500 micrometers.

8. A method of making through silicon vias utilizing carbon nanotubes, comprising:
coating a bottom surface of a silicon wafer with a carbon nanotube catalyst layer followed by support layer;
etching a plurality of holes through the silicon wafer such that the plurality of holes extend from a top surface of the silicon wafer to the bottom side of the silicon wafer but do not penetrate the carbon nanotube catalyst layer or support layer; and
growing carbon nanotubes through at least a portion of the plurality of holes.

9. The method of claim 8, further comprising patterning the top surface of the silicon wafer.

10. The method of claim 8, wherein the carbon nanotube catalyst layer is a metal.

11. The method of claim 10, wherein the metal is iron, nickel, or cobalt.

12. The method of claim 8, wherein the carbon nanotube catalyst layer is about 0.5 to about 10 nanometers in thickness.

13. The method of claim 8, wherein the support layer is 5 micrometers or less in thickness.

14. The method of claim 8, wherein the silicon wafer is about 150 to about 500 micrometers in thickness.

15. The method of claim 8, wherein the silicon wafer mold is further selectively metalized with an additional metal to serve as an electrical contact layer.

16. The method of claim 8, further comprising forming metal electrical contacts on at least a portion of the carbon nanotubes.

17. The method of claim 8, wherein the carbon nanotube catalyst layer is also an electrical contact layer.

18. The method of claim 8, further comprising separating the silicon wafer mold from the carbon nanotube catalyst layer and support layer via shearing, chemical or plasma etching, or polishing.

19. The method of claim 8, wherein the support layer is an oxide layer.

20. The method of claim 8, wherein the support layer is made of a material having a higher melting temperature than the carbon nanotube deposition temperature.

21. The method of claim 8, wherein the carbon nanotubes are grown using a chemical vapor deposition process.
